(19) United States
(12) Patent Application Publication
(10) Pub. No.: US 2009/0102335 A1
(43) Pub. Date: Apr. 23, 2009

(54) WORKSTATION

(76) Inventors: David Hancock, Chippewa Falls, WI (US); Travis Hart Edinger, Bloomer, WI (US)

Correspondence Address: FOLEY & LARDNER LLP, 777 EAST WISCONSIN AVENUE, MILWAUKEE, WI, 53202-5306, US

(21) Appl. No.: 11/875,653

(22) Filed: Oct. 19, 2007

(51) Int. Cl. H05K 5/00

(52) U.S. Cl. 312/223.3; 312/223.1

(57) ABSTRACT

A workstation is provided that includes a base, a first worksurface supported by the base and a housing supported by the base. The first worksurface defines an opening and the housing is movable within the opening. The housing is configured support a display monitor (e.g., a flat screen monitor, etc.) and has a receptacle configured to support an input device (e.g., keyboard, etc.). The workstation also includes a second work surface supported atop the housing and an actuator coupled between the base and the housing for selectively moving the housing in a vertical direction between a stowed position and a use position. The second worksurface is substantially aligned with the first worksurface when the housing is in the stowed position. The housing is configured to be selectively moved from the use position to one of the stowed position and an intermediate position by applying a downward force to the second worksurface.

### BACKGROUND

The present disclosure relates generally to desks or workstations configured to support a display device (e.g., computer monitor, flat-screen, etc.) and provide a working surface for a user. More specifically, the present disclosure relates to workstations that allow for the display device to be selectively moved between an extended use position and a retracted stowed position.

It would be desirable to provide a desk or a workstation configured to support a display device, and one or more peripheral devices related thereto (e.g., keyboard, mouse, etc.), within a display housing that can be selectively moved by a user between an extended use position and a retracted stowed position (and the various positions therebetween) without worrying that the one or more peripheral devices will interfere with the movement of the display housing. Such a system would provide an improved workstation that is less susceptible to failure in the event that the one or more peripheral devices inadvertently moves while stowed. It would also be desirable to provide a desk or workstation having such a feature that is also configured to provide a sizable working surface for the user when the display housing is in both the use position and the stowed position. It would further be desirable to provide a desk or workstation having a display housing that can lowered the stowed position or to a height less than when in the use position by simply applying a force to a top of the display housing. However, the problems posed by these types of arrangements are particularly complicated because they exist within the complexity of the overall a workstation. For example, sizing constraints of a workstation, a balance between providing a workstation that is adequately functional as both a computer desk and a working desk, the positioning of a display device and the various components related thereto within the workstation, etc. Accordingly, the selection of a solution may result in unforeseen sizing and component complications, cost increases, manufacturing efficiency losses, expensive part configurations, etc.

### SUMMARY

An exemplary embodiment relates to a workstation. The workstation includes a base, a first worksurface supported by the base and a housing supported by the base. The first worksurface defines an opening and the housing is movable within the opening. The housing is configured support a display monitor and has a receptacle configured to support an input device. The workstation also includes a second work surface supported atop the housing and an actuator coupled between the base and the housing for selectively moving the housing in a vertical direction between a stowed position and a use position. The second worksurface is substantially aligned with the first worksurface when the housing is in the stowed position. The housing is configured to be selectively moved from the use position to one of the stowed position and an intermediate position by applying a downward force to the second worksurface.

Another exemplary embodiment relates to a workstation. The workstation includes a work surface and a compartment for housing a display monitor. The compartment has a base that includes a receptacle for receiving an input device and for biasing the input device away from a front portion of the compartment. The workstation also includes an actuator device configured to selectively move the compartment in a vertical direction between a first position wherein an upper surface of the compartment is substantially aligned with the work surface and a second position wherein the upper surface of the compartment is above the work surface. The compartment is configured to be selectively moved from the second position to at least one of the first position and an intermediate position by applying an external downward force to the compartment.

Another exemplary embodiment relates to a desk. The desk includes a first workstation including a first display housing. The first display housing has a first surface and is configured to move between a first position and a second position. The desk also includes a second workstation including a second display housing. The second display housing has a second surface and is configured to move between the first position and the second position. The desk further includes a worksurface extending between the first workstation and the second workstation. The worksurface has a first aperture configured to receive the first display housing and a second aperture configured to receive the second display housing. The desk further includes a first actuator for selectively moving the first display housing and a second actuator for selectively moving the second display housing independent of the first display housing. The first and second display housings are configured to be selectively moved independently of each other from the second positions to at least one of the first positions and intermediate positions by applying an external downward force to the first and second display housings respectively.

### BRIEF DESCRIPTION OF THE DRAWINGS

FIG. 1 is a front perspective view of a workstation according to an exemplary embodiment shown in an extended use position.

FIG. 2 is a front perspective view of the workstation of FIG. 1 shown in a retracted stowed position.

FIG. 3 is a front perspective view of the workstation of FIG. 1 shown in an intermediate position.

FIG. 4 is a rear perspective view of the workstation of FIG. 1 shown with a rear panel removed.

FIG. 5 is a front perspective view of a workstation shown with a keyboard stowed in a substantially vertical position.

FIG. 6 is another front perspective view of the workstation of FIG. 1 and showing a storage well for a keyboard.

FIG. 7A is a side elevational view of the workstation of FIG. 1.

FIG. 7B is a detailed cross sectional view of the storage well shown in FIGS. 6 and 7A.

FIG. 8 is a front perspective view of a workstation according to another exemplary embodiment shown in an extended use position.

FIG. 9 is a front perspective view of the workstation of FIG. 8 shown in a retracted stowed position.

FIG. 10 a rear perspective view of the workstation of FIG. 8 shown with a one rear panel removed.

### DETAILED DESCRIPTION

Referring generally to the FIGURES, a workstation 10 and various components thereof are shown according to exemplary embodiments. Workstation 10 may be a self-supporting desk or table suitable for use in a variety of environments including, but not limited to, an office, classroom, lecture hall, conference room, residential settings, etc. Workstation 10 is configured to be conveniently transformed (e.g., reconfigured, adjusted, modified, etc.) by a user from a workstation having a substantially planar and relatively continuous working surface to a workstation supporting a display device in a position accessible (e.g., visually accessible, etc.) to the user of the workstation. Such a configuration may find particular utility in an interactive educational, training and/or learning type setting wherein it may be desirable to provide the user with access to a display monitor at select times and to remove or reduce such access at other times.

To facilitate the transformation of workstation 10 between a workstation that provides a substantially planar and relatively continuous working surface and a workstation that supports a display device in a position accessible to the user of the workstation, workstation includes an actuator (e.g., gas spring, pneumatic cylinder, etc.) and a corresponding user interface (e.g., a push-button, etc.). Manipulation of the user interface causes the display device to be moved to a raised position. A single manipulation may cause the display device to be moved to the use position or, alternatively, to an intermediate position. To lower the display device to the stowed or an intermediate position, the user (or someone standing near workstation 10) applies a downward force to a housing the supports the display device. For example, a downward force may be applied by using one's hand to push down on the housing. Once the downward force is removed, the actuator will latch and hold display device in the position the display device was in when the downward force was removed. This allows the display device to achieve a number of different intermediate positions making it particularly suitable for the interactive learning environment.

Before discussing the details of the workstation 10, it should be noted at the outset that references to “front,” “back,” “rear,” “upper,” “lower,” “right,” and “left” in this description are merely used to identify the various elements as they are oriented in the FIGURES, with “front,” “back,” “rear,” “upper,” “lower,” “right,” and “left” being relative to a user positioned (e.g., seated, etc.) at the workstation 10. These terms are not meant to limit the element which they describe, as the various elements may be oriented differently in various applications.

It should further be noted that for purposes of this disclosure, the term “coupled” means the joining of two members directly or indirectly to one another. Such joining may be stationary in nature or moveable in nature and/or such joining may allow for the flow of fluids, electricity, electrical signals, or other types of signals or communication between the two members. Such joining may be achieved with the two members or the two members and any additional intermediate members being integrally formed as a single unitary body with one another or with the two members or the two members and any additional intermediate members being attached to one another. Such joining may be permanent in nature or alternatively may be removable or releasable in nature.

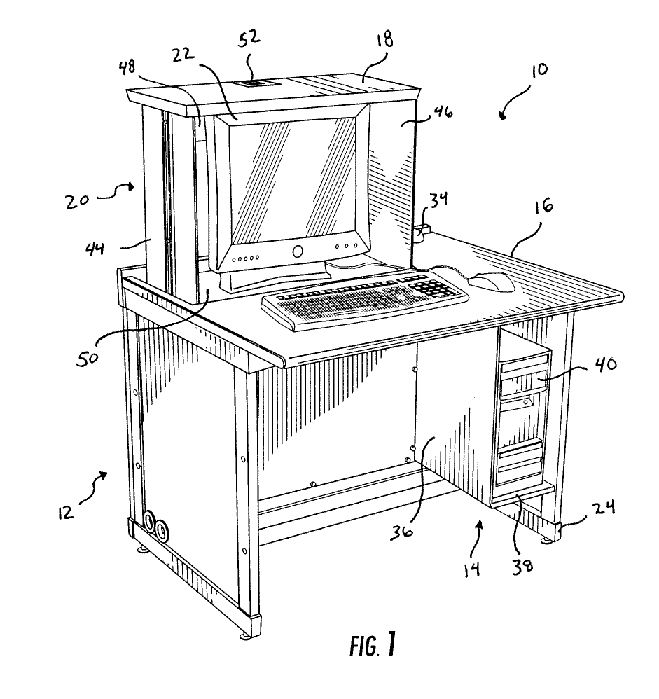

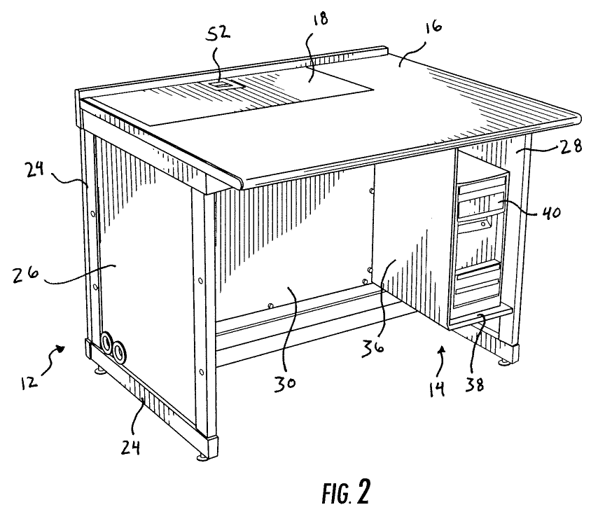

Referring to FIGS. 1 through 4, workstation 10 generally comprises a base 12 (shown as including a cabinet or storage subsystem 14), a first platform (e.g., panel, tabletop, worksurface, etc.), shown as a first working surface 16, a second platform (e.g., panel, tabletop, worksurface, etc.), shown as a second working surface 18, and a movable housing (e.g., support system, support assembly, etc.), shown as a display housing 20. Second working surface 18 is supported at a top of display housing 20. Display housing 20 is configured to support a display device (e.g., computer monitor, television, etc.), shown as a flat screen display 22, and is selectively movable between an extended use position (shown in FIG. 1) and a retracted stowed position (shown in FIG. 2). As detailed below, display housing 20 is also configured to support flat screen display 22 at any of the various positions (e.g., intermediate positions, etc.) between the use position and the stowed position.

In the use position, display housing 20 supports flat screen display 22 at a position wherein the flat screen display 22 is at viewable or otherwise accessible to a user. In the stowed position, display housing 20 supports flat screen display 22 at a position wherein the display device is generally concealed from the user. To achieve the stowed position, a portion of display housing 20 is lowered relative to base 12 so that display device is below first working surface 16 and second working surface 18 is substantially coplanar with first working surface 16. With second working surface 18 being substantially coplanar with first working surface 16, working surfaces 16, 18 cooperate to define a relatively large and continuous working surface for a user.

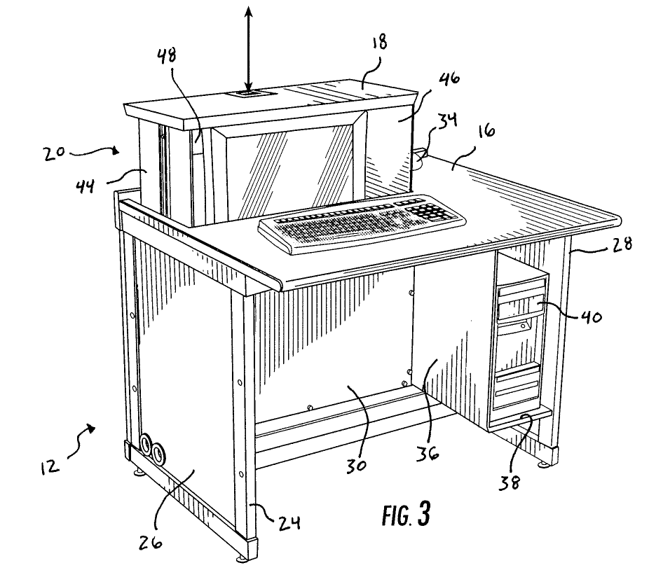

Referring to FIG. 3, display housing 20 is also configured to support flat screen display 22 at one or more positions between the use position and the stowed position (collectively referred to for purposes of this disclosure as an intermediate position). The intermediate position may advantageously provide a position wherein flat screen display 22 is at least partially viewable by a user without substantially blocking or otherwise interfering with the ability of a user to see someone (e.g., presenter, speaker, teacher, trainer, etc.) or something (e.g., chalkboard, whiteboard, main display screen, etc.) positioned in front of workstation 10 and/or the ability of someone positioned in front of workstation 10 from seeing the user.

Referring again to FIGS. 1 through 4, base 12 comprises one or more structures configured to serve as the support or foundation for the remaining components of workstation 10. According to the embodiment illustrated, base 12 includes a frame structure formed of one or more frame members 24. Frame members 24 are made of a variety of rigid materials (e.g., steel, aluminum, plastic, composite material, wood, etc.) which can be selected depending on the particular application and/or the conditions in which workstation 10 will be used. According to the embodiment illustrated, base 12 also includes one or more covering members (e.g., partitions, walls, privacy screens, modesty panels, etc.), shown as a left side panel 26, a right side panel 28 and a rear panel 30. Panels 26, 28 and 30 cooperate to define a substantially rectangular box-like structure having an open front configured to receive a user. Panels 26, 28 and 30 may be provided for aesthetic purposes (e.g., to conceal frame members 24, etc.) and/or may be provided for functional purposes, (e.g., to offer privacy to a user seated at workstation 10, to reduce the likelihood that contaminants will interfere with the components of workstation 10 and/or the components of any devices supported by workstation 10, etc.). Panels 26, 28 and 30 are formed of a relatively rigid material that may be resistant to corrosion, lightweight and/or relatively easy to maintain or clean.

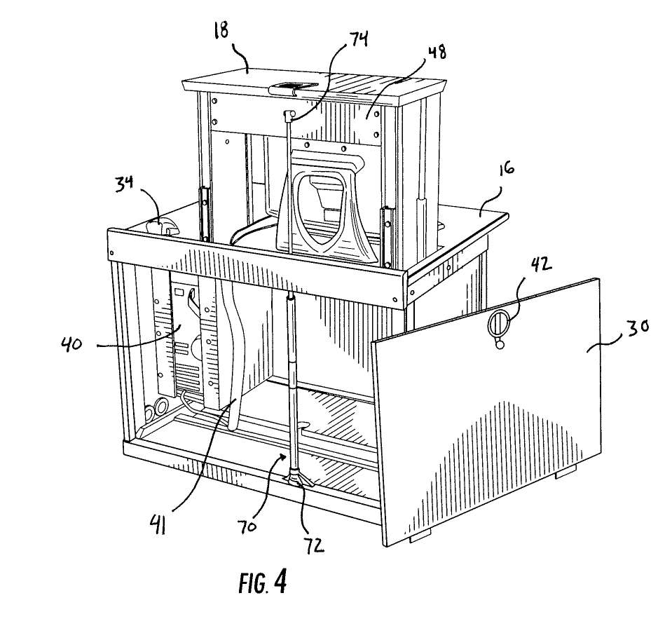

Referring to FIG. 4 in particular, rear panel 30 is configured to be selectively removed to provide a user and/or technician with access to the components of workstation 10 and/or the devices supported by workstation 10. To facilitate removal of rear panel 30, a handle or latch 42 is provided at an upper portion of rear panel 30. Rear panel 30 is configured to be removed by manipulating (e.g., turning, etc.) latch 42 and lifting rear panel 30 away from base 12. Latch 42 may be provided with a locking device to prevent people who are unauthorized from removing rear panel 30.

According to the embodiment illustrated, frame members 24 are shown at a left side, a right side and a rear side of workstation 10. Frame members 24 are shown as comprising vertically extending frame members 24 which are coupled to horizontally extending frame members 24. To facilitate the coupling of panels 26, 28 and 30 to frame members 24, frame members 24 include a series of spaced apertures 32 configured to receive a suitable fastener (e.g., bolt, screw, clip, rivet, etc.). According to the various alternative embodiments, panels 26, 28 and 30 may be coupled to frame members 24 using any other suitable technique (e.g., friction fit, interference fit, welding, adhesive, etc.). According to further alternative embodiments, panels 26, 28 and 30 may be integrally formed with frame members 24 to form one-piece unitary body sections.

Referring back to FIGS. 1 through 3 and according to the embodiment illustrated, base 12 is further shown as including storage unit 14. Storage unit 14 is shown as being provided along a right side of workstation 10 and includes a vertical side surface 36 and a horizontal bottom surface 38. Storage unit 14 provides a receptacle that is accessible to a user seated at workstation 10. According to an exemplary embodiment, storage unit 14 has an open front and is configured to support a computer 40 that is electrically coupled to flat screen display 22. Referring to FIG. 4, a flexible cable guide 41 is provided so that wires or cables can easy pass between storage unit 14 and display housing 20. Flexible cable guide 41 may protect against undue tangling or pulling of cables from their sources. According to the various alternative embodiments, storage unit 14 may be configured to support other objects (e.g., electronics, wireless systems, one or more drawers, etc.) and may have any of a variety of suitable configurations.

According to the various alternative embodiments, base 12 may be replaced with any of a variety of suitable bases or structures for supporting first working surface 16 and/or any of the other components of workstation 10. For example, base 12 may be in the form of two or more upright support columns (e.g., legs, posts, etc.) spaced apart to support first working surface 16. Such support columns may have a fixed length, or alternatively may be adjustable in length to provide a workstation with a height adjustable worksurface.

First working surface 16 is supported by base 12 and provides a working surface (e.g., writing surface, support surface, etc.) for a user of workstation 10. According to the embodiment illustrated, first working surface 16 is a generally rectangular worksurface having an aperture or opening configured to receive display housing 20 and second working surface 18. According to an exemplary embodiment, first working surface 16 is of sufficient size to provide a user with a functional working surface even when display housing 20 is in its extended use position. For example, first working surface 16 may have a width between approximately 24 inches and approximately 60 inches and a depth between approximately 18 inches and approximately 42 inches. According to the various alternative embodiments, first working surface 16 may be provided in a wide variety of configurations and/or shapes or dimensions or materials and construction. For example, first working surface 16 may have a width and/or depth with dimensions greater than or less than those described above.

According to an exemplary embodiment, first working surface 16 is fixedly coupled to base 12 at a position that is substantially perpendicular to panels 26, 28 and 30. According to the embodiment illustrated, first working surface 16 is fixedly coupled to frame members 24 of base 12. To facilitate the coupling of first working surface 16 to frame members 24, one or more brackets in combination with one or more fasteners (e.g., bolts, screws, clips, rivets, etc.) may be used. According to the various alternative embodiments, first working surface 16 may be coupled to frame members 24 using any other suitable technique (e.g., friction fit, interference fit, welding, adhesive, etc.). According to further alternative embodiments, first working surface 16 may be integrally formed with one or more of frame members 24 and/or panels 26, 28 and 30 to form a one-piece unitary body.

As shown in FIGS. 1, 3 and 4, first working surface 16 may optionally include a second aperture or opening under a cover 34 that allows cables, cords, or other articles to pass through first working surface 16. Such an opening may a allow a user to be provided with convenient access to an electrical, communication, video and/or audio port or outlet. Although not illustrated, first working surface 16 may optionally support a movable tray configured to receive a keyboard, mouse, or any other object (e.g., notepads, writing utensils, supplies, etc.). For example, a movable tray configured to move between a stowed position and a use position may be coupled to an underside of first working surface 16.

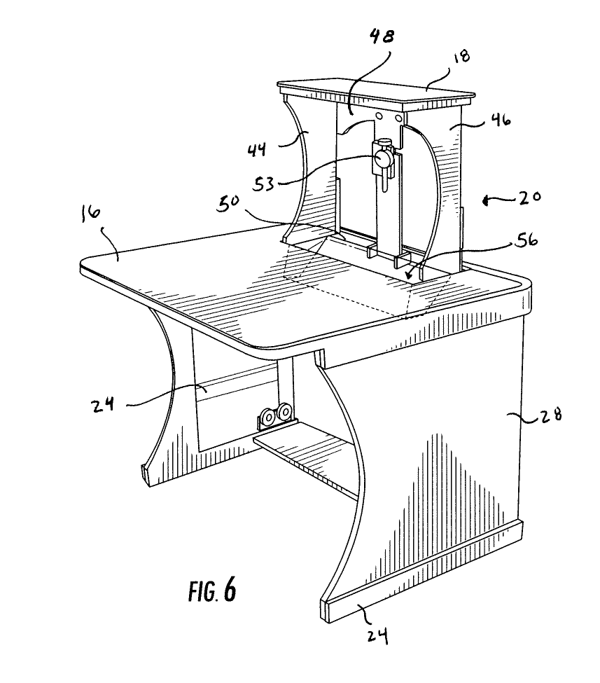

Referring to FIGS. 1 and 3 through 7b, display housing 20 is shown as a box-like structure that includes a first side wall 44, a second side wall 46 spaced apart in a lateral direction from first side wall 44, a rear wall 48 and a base 50. Display housing 20 is sized to receive and support flat screen display 22. Flat screen display 22 may be supported by base 50 (as shown in FIG. 1) or may be supported by rear wall 48 (as shown in FIG. 6). According to an exemplary embodiment, the overall depth of display housing 20 is limited so that a functional working surface can still be provided for a user when display housing 20 is in the extended use position.

Supported atop display housing 20 and fixedly coupled thereto is second working surface 18. Second working surface 18 is configured to be substantially flush or coplanar with first working surface 16 when display housing 20 is in the retracted stowed position (as shown in FIG. 2). Second working surface 18 has a shape and size corresponding to the opening in first working surface 16 configured to receive display housing 20. Preferably, there will be little or no gap between second working surface 18 and first working surface 16 when display housing 20 is in the retracted stowed position. Second working surface 18 may optionally include a handle or latch 52 to assist a user in moving display housing 20 between the use and stowed positions and/or to secure display housing 20 in the stowed position. Latch 52 may be provided with a locking device to restrict the movement of display housing 20 from the stowed position. Such a feature may reduce damage to flat screen display 22 caused by vandalism and/or during transport of workstation 10.

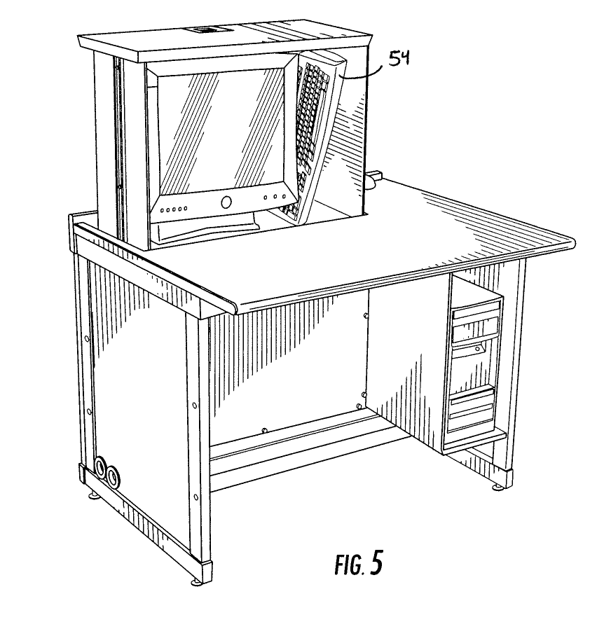

FIG. 5 shows a workstation wherein a keyboard 54 is stowed by being positioned on its end and leaning against a side wall of the display housing. Keyboard 54 may be relatively unstable in such a stowed position, particularly if keyboard 54 includes rounded or otherwise curved ends. For example, in such a position, keyboard 54 may fall or otherwise move from its initial tilted position. Allowing keyboard 54 to fall or otherwise move may interfere with the functional operation of the workstation. If keyboard 54 moves while the display housing is being moved between the use and stowed position and/or while the display housing is in the stowed position, keyboard 54 may interfere with the movement of the display housing. For example, keyboard 54 may fall or otherwise move backwards or forwards and come to rest in a position wherein keyboard 54 extends beyond the periphery of the display housing. With a portion of keyboard 54 extending beyond the periphery of the display housing, keyboard 54 may engage (e.g., strike, etc.) working surface 16 as the display housing is moved thereby hindering (e.g., jamming, restricting, etc.) the movement of the display housing.

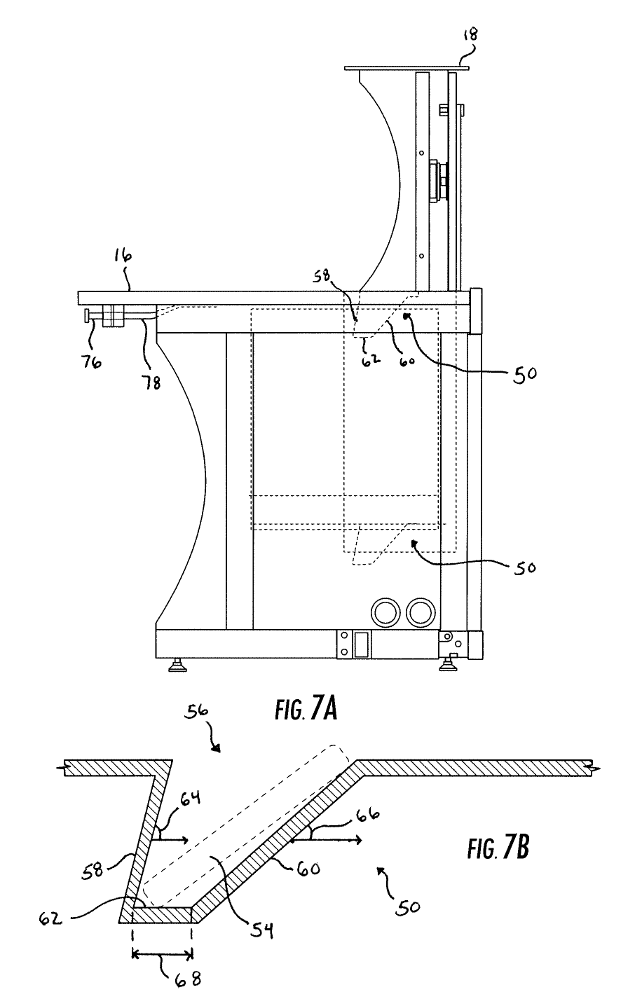

To reduce the likelihood that keyboard 54 will interfere with the movement of display housing 20, base 50 of display housing 20 includes a receptacle (e.g., cavity, etc.), shown as a storage well 56, for receiving keyboard 54 when stowed. Referring to FIGS. 6 through 7B, storage well 56 is shown as extending laterally across the front portion of base 50 between first side wall 44 and second side wall 46. According to the embodiment, storage well 56 extends across the entire from portion of base 50. According to the various alternative embodiments, storage well 56 may extend across only a portion of distance between first side wall 44 and second side wall 46. For example, if the distance between first side wall 44 and second side wall 46 is significantly greater than the width of a typical keyboard that will be used with flat screen display 22, the lateral width of storage well 56 may be sized more closely to the width of the keyboard.

Storage well 56 is configured to urge (e.g., bias, direct, etc.) keyboard 54 toward a position wherein keyboard 54 is unlikely to interfere with the vertical movement of display housing 20. According to an exemplary embodiment, storage well 56 is configured to urge keyboard 54 away from a front edge of display housing 20. According to the embodiment illustrated, storage well 56 is defined by a front surface or wall 58, a rear surface or wall 60, a bottom surface or wall 62 and a pair of side surfaces or walls 65, 67 provided at each lateral end of storage well 56. Rear wall 60 is tilted or angled towards a rear portion of workstation 10 while bottom wall 62 is substantially horizontal or flat. By angling rear wall 60 towards the rear of workstation 10, keyboard 54 is urged to fall back away from the front edge of display housing 20 when placed therein, thereby reducing the likelihood that keyboard 54 will interfere with the movement of display housing 20. According to an exemplary embodiment, rear wall 60 is orientated an angle 64 (relative to a horizontal plane) that is between approximately 10 degrees and approximately 60 degrees. According to the embodiment illustrated, angle 64 is approximately 30 degrees. According to the various alternative embodiments, rear wall 60 may be orientated at any of number of angles. For example, rear wall 60 may be orientated at an angle greater than or less than those described above.

Front wall 58 is a substantially upright wall that may be substantially vertical or slightly angled. According the embodiment illustrated, front wall 58 is shown as being angled towards the rear of workstation 10. Angling front wall 58 towards the rear of workstation 10 may further assist in urging keyboard 54 away from the front edge of display housing 20 when stowed therein. The angle of front wall 58 (relative to a horizontal plane) is greater than the angle of rear wall 60 (relative to the same horizontal plane) to make it less troublesome for a user to remove keyboard 54 from storage well 56 when its removal is desired. If front wall 58 were to be angled less than rear wall 60, keyboard 54 may catch or be relatively blocked by front wall 58 when a user attempts to remove keyboard 54 from storage well 56. This may be particularly true if a user is seated at workstation 10 and is attempting to pull keyboard 54 out of storage well 56 and towards herself or himself. According to an exemplary embodiment, front wall 58 is orientated an angle 66 (relative to a horizontal plane) that is between approximately 60 degrees and approximately 90 degrees. According to the embodiment illustrated, angle 66 is approximately 75 degrees. According to the various alternative embodiments, front wall 58 may be orientated at any of number of angles. For example, front wall 58 may be orientated at an angle greater than or less than those described above.

Bottom wall 62 of storage well 54 is configured to support the front or rear edge of keyboard 54 when keyboard 54 is placed in storage well 54. Referring to FIG. 7B in particular, bottom surface 62 is a substantially flat wall that has a depth 68 that is sized to further assist in urging keyboard 54 away from the front of display housing 20. According to an exemplary embodiment, depth 62 is limited so that keyboard 54 cannot sit flat on its front or rear edge without contacting an upper edge of front wall 58 and thereby being urged away from the front of display housing 20.

According to the various alternative embodiments, one or more of front wall 58, bottom wall 62 and rear wall 60 may be combined as a relatively continuous wall. For example, bottom wall 62 and rear wall 60 may be combined as a curved surface that has a profile that is substantially parabolic in shape. According to further alternative embodiments, the receptacle supporting keyboard 54 may have any of a variety of profiles that bias the keyboard towards a rear of workstation 10.

To facilitate the vertical movement of display housing 20 relative to base 12 between the stowed and use positions, one or more lift devices (e.g., height adjusting mechanism, etc.), shown as an actuator 70 in FIG. 4, are provided. Actuator 70 can be implemented many possible ways (e.g., with electrically, pneumatically or hydraulically actuated motors or cylinders, etc.). According to an exemplary embodiment, actuator 70 is a pneumatic cylinder or gas spring having a first end 72 coupled to base 12 and a second end 74 coupled to display housing 20. According to the embodiment illustrated, second end 74 is coupled directly to rear wall 48 of display housing 20. According to various alternative embodiments, positioning device may be any of a variety of air, gas, liquid, elastomer, spring, or hydraulic devices, shocks, or shock absorber, dashpot mechanisms, air spring, cylinders or combinations thereof.

Actuator 70 is a continuously adjustable positioning mechanism is used to provide adjustment of the height of display housing 20 relative to base 12. According to an exemplary embodiment, actuator 70 is a self-locking gas spring that provides counterbalancing forces for raising display device 20, yet is self-locking for infinite and precise positioning of display housing 20 in the various positions between the stowed position and the use position. Unlocking of actuator 70 is controlled by actuating an interface (e.g., switch, lever, etc.), shown as a release button 76 in FIG. 7A. When actuated, release button 76 acts through a conduit system 78 coupled to actuator 70 (via a valve, such as a hydraulic valve) to release the energy contained within the cylinder and thereby raise display housing 20.

According to an exemplary embodiment, release button 76 is supported at a position that is relatively easy for a user seated at workstation 10 to access. According to the embodiment illustrated, release button 76 is coupled to an underside and near a front edge of first working surface 16. Any of a variety of fasteners may be used to secure release button 76 to first working surface 16 (e.g., screws, bolts, clips, rivets, brackets, hangers, etc.).

To transform workstation 10 from the stowed position to the use position (i.e., raise display housing 20), the user actuates release button 76 which in turn actuates a valve on actuator 70. According to an exemplary embodiment, valve is configured so that a single actuation of release button 76 (e.g., a single press and release, etc.) causes movable display housing 20 to move into the use position. According to various alternative embodiments, valve may be configured so that movable display support system will stop moving toward the use position once a user stops actuating release button 76. Thus, a user would be required to continue to actuate release button 76 in order for display housing 20 to reach the fully extended use position. Such an embodiment may allow the user to position display housing 20 in an intermediate position without having to wait for display housing 20 to first reach the use position.

To transform workstation 10 from the use position to the stowed or intermediate positions (i.e., lower display housing 20), the user (or someone standing near workstation 10) applies a downward force to display housing 20. For example, a downward force may be applied by using one's hand to push down on second working surface 18. Preferably, actuator 70 is configured so that the amount of force required to lower movable display support system to the stowed or intermediate positions is relatively small. This allows a typical user of workstation 10 to lower movable display support system with minimal effort. Once the downward force is removed, the valve of actuator 70 will latch and hold display housing 20 at the position display housing 20 was in when the downward force was removed. This allows display housing 20 to achieve a number of different intermediate positions making it particularly suitable for an interactive learning environment.

To facilitate the guided movement of display housing 20 relative to base 12, a guide system is provided. According to an exemplary embodiment, the guide system comprises one or more guides (e.g., runners, rails, drawer slides, etc.), shown as track members 80, supported between display housing 20 and base 12. Track members 80 are shown as extending in a substantially vertical direction and being coupled to outer surfaces of side walls 44, 46 of display housing 20. One or more track members 80 may also be provided along rear wall 48 of display housing 20 (as shown in FIG. 4). It should be noted that the guide system may include any number of tracks or rails and/or any other configuration suitable for providing the guided movement of display housing 20.

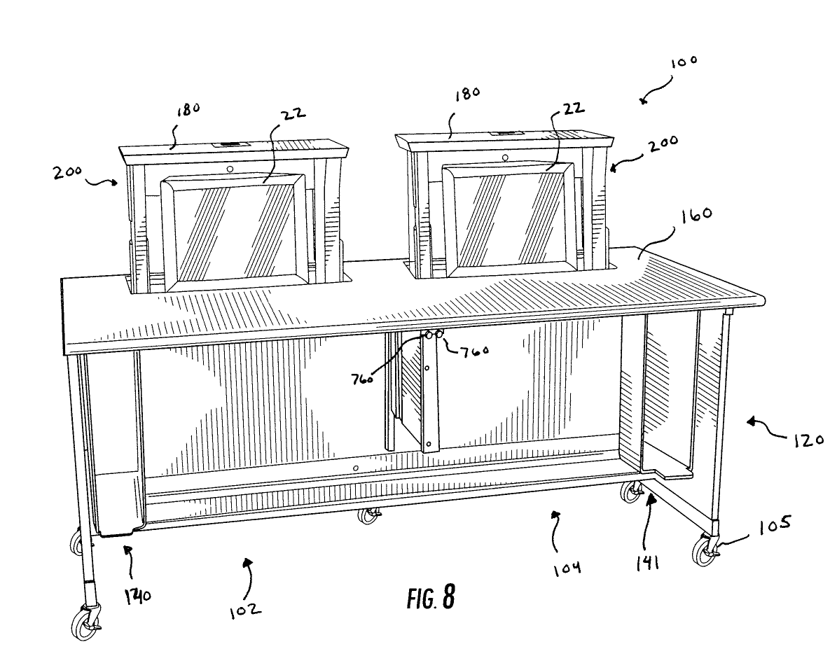

Referring to FIGS. 8 through 10, workstation 100 is shown according to another exemplary embodiment. According to such an embodiment, workstation 100 is configured to simultaneously accommodate more than one user. According to the embodiment illustrated, workstation 100 includes a first station 102 and a second station 104 and is thereby configured to simultaneously accommodate two users. Workstation 100 generally comprises a base 120 (shown as including a cabinets or storage subsystems 140 and 141), a first platform (e.g., panel, tabletop, worksurface, etc.), shown as a first working surface 160. First working surface 160 extends continuously between first station 102 and second station 104.

For each station 102, 104, workstation 100 includes a second platform (e.g., panel, tabletop, worksurface, etc.), shown as a second working surface 180, and a movable housing (e.g., support system, support assembly, etc.), shown as a display housing 200. Second working surfaces 180 is supported atop display housings 200, which are configured to support a display devices (e.g., computer monitors, televisions, etc.), shown as a flat screen displays 22.

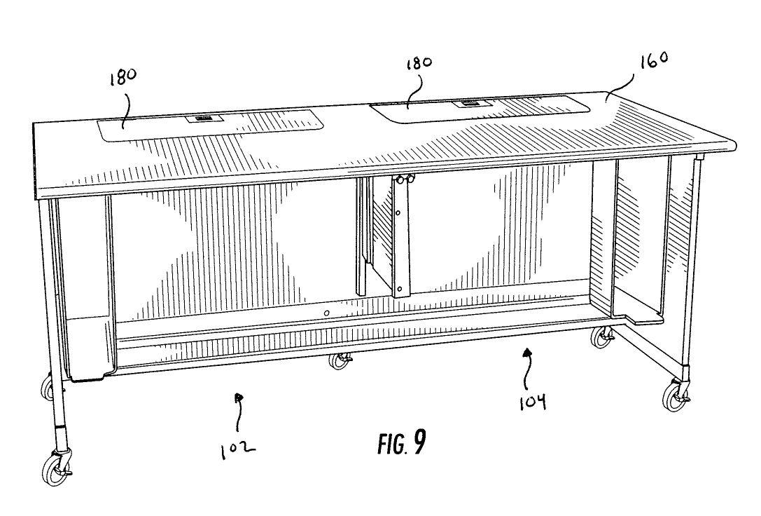

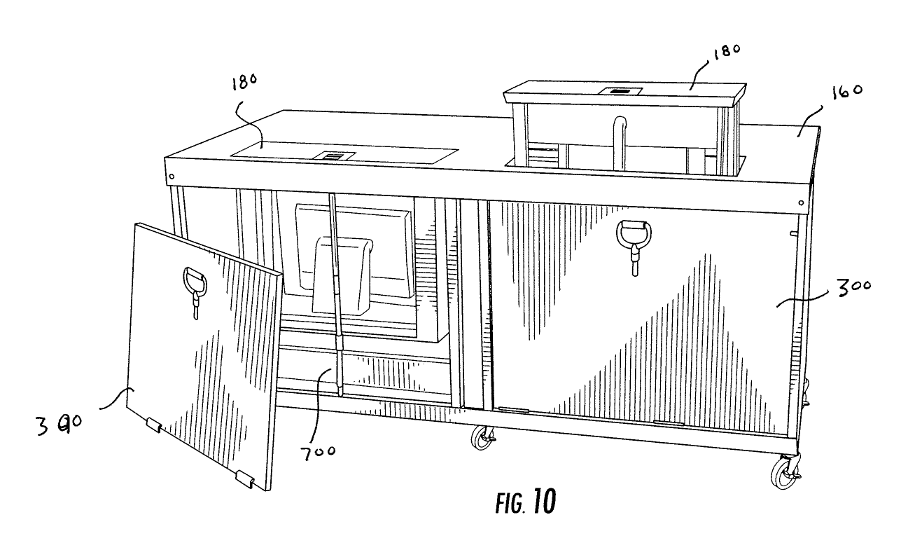

Each display housing 200 is independently movable between the extended use position (shown in FIG. 8) and the retracted stowed position (shown in FIG. 9). The independent movement of display housings 200 is best shown in FIG. 10, wherein display housing 200 at first station 102 is provided in an intermediate position and display housing 200 at second station 104 is provided in the stowed position. To facilitate the independent movement of each display housing 200, each station 102, 104 is provided with a separate actuator 700 and user interface 760.

According to an exemplary embodiment, first working surface 160 includes a separate opening for receiving display housings 200 and second working surfaces 180. Providing discrete or separate openings within first work surface 160 will increase the working surface that is available to a user whose display housing 200 is in the stowed position when the other user has his or her display housing 200 in the use or intermediate positions.

Providing multiple user stations within a single workstation results in a workstation that is likely to be more efficient (e.g., cost, time, etc.) to manufacture than a manufacturing a separate workstation for each user station required. Such a configuration may also simplify the transportation of the workstations between various locations. To further facilitate convenient transportation between various locations, workstation 100 is shown as including wheels or casters 105 that support base 120 off a ground surface.

It is important to note that the construction and arrangement of the workstation shown in the exemplary embodiments is illustrative only. Although only a few embodiments of the workstation have been described in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter recited in the claims. For example, elements shown as integrally formed may be constructed of multiple parts or elements, elements shown as multiple parts may be integrally formed, the position of elements may be reversed or otherwise varied, and the nature or number of discrete elements or positions may be altered or varied. Further, it should be noted that flat screen display 22 may be of any type, including flat panel display panels or other types of video monitors (e.g., CRT) or any other type of data or information display device or appliance. Flat screen display 22 may be associated with any type of appliance or device, such as a computing device or a television or network, etc. Further still, it should be noted that flat screen display 22 may be supported within display housing 20 in a manner that allows a user to optimize the viewing angle/position (such as to remove glare or enhance visibility) of flat screen display 22 or to further enhance sharing/revealing or privacy/concealment of information. For example, a rotatable base or a functionally equivalent bracket may be provided at display housing 20 (see FIG. 6 as having a such a bracket 53). Alternatively, flat screen display 22 may be fixed to display housing such that the tilt/angle of flat screen display 22 is substantially nonadjustable. Accordingly, all such modifications are intended to be included within the scope of the present invention as defined in the appended claims. The order or sequence of any process or method steps may be varied or re-sequenced according to alternative embodiments. Other substitutions, modifications, changes and omissions may be made in the design, operating conditions and arrangement of the exemplary embodiments without departing from the scope of the present inventions as expressed in the appended claims.

What is claimed is:

1. A workstation comprising:
a base;
a first worksurface supported by the base and defining an opening;
a housing supported by the base and movable within the opening, the housing being configured support a display monitor and having a receptacle configured to support an input device;
a second work surface supported atop the housing; and
an actuator coupled between the base and the housing for selectively moving the housing in a vertical direction between a stowed position and a use position, the second worksurface being substantially aligned with the first worksurface when the housing is in the stowed position,
wherein the housing is configured to be selectively moved from the use position to at least one of the stowed position and an intermediate position by applying a downward force to the second worksurface.

2. The workstation of claim 1 wherein the housing is configured to support a flat screen display monitor.

3. The workstation of claim 2 wherein the receptacle is provided at a base portion of the housing and extends in a lateral direction.

4. The workstation of claim 3 wherein the housing includes a first side wall and a second side wall, the receptacle extending substantially the entire distance between the first side wall and the second side wall.

5. The workstation of claim 3 wherein the receptacle is configured to bias the input device away from a front portion of the housing.

6. The workstation of claim 5, wherein receptacle comprises:
a front wall;
a rear wall angled towards a rear portion of the workstation; and
a bottom wall extending between the front wall and the rear wall.

7. The workstation of claim 6 wherein the front wall is substantially upright relative to the rear wall.

8. The workstation of claim 7 wherein the front wall is angled towards the rear portion of the workstation, the front wall being provided at an angle that is greater than an angle of the rear wall.

9. The workstation of claim 7 wherein the bottom wall has a depth that is configured to prevent the input device from sitting substantially flat along an edge of the input device.

10. The workstation of claim 1 wherein the actuator holds the housing at whatever position the housing was in when the downward force is removed from the second worksurface.

11. The workstation of claim 10 wherein the actuator is a gas spring configured to be selectively actuated by manipulating a user interface coupled to the workstation.

12. A workstation comprising:
a work surface;
a compartment for housing a display monitor, the compartment having a base that includes a receptacle for receiving a input device and for biasing the input device away from a front portion of the compartment;
an actuator device configured to selectively move the compartment in a vertical direction between a first position, wherein an upper surface of the compartment is substantially aligned with the work surface, and a second position, wherein the upper surface of the compartment is above the work surface,
wherein the compartment is configured to be selectively moved from the second position to at least one of the first position and an intermediate position by applying an external downward force to the compartment.

13. The workstation of claim 12 wherein receptacle is provided at a base of the compartment and comprises:
a front wall;
a rear wall angled towards a rear portion of the workstation; and
a bottom wall extending between the front wall and the rear wall.

14. The workstation of claim 13 wherein the front wall is substantially upright relative to the rear wall.

15. The workstation of claim 14 wherein the front wall is angled towards the rear portion of the workstation, the front wall being provided at an angle that is greater than an angle of the rear wall.

16. The workstation of claim 13 wherein the bottom wall has a depth that is configured to prevent the input device from sitting substantially flat along an edge of the input device.

17. The workstation of claim 13 wherein the display monitor is configured to be supported by the base of the compartment rearward of the receptacle.

18. The workstation of claim 13 wherein the display monitor is configured to be supported by a rear wall of the compartment.

19. A desk comprising:
a first workstation including a first display housing, the first display housing has a first surface and is configured to move between a first position and a second position;
a second workstation including a second display housing, the second display housing has a second surface and is configured to move between the first position and the second position;
a worksurface extending between the first workstation and the second workstation, the worksurface having a first aperture configured to receive the first display housing and a second aperture configured to receive the second display housing;
a first actuator for selectively moving the first display housing; and
a second actuator for selectively moving the second display housing independent of the first display housing,
wherein the first and second display housings are configured to be selectively moved independently of each other from the second positions to at least one of the first positions and intermediate positions by applying an external downward force to the first and second display housings respectively.

20. The desk of claim 19 wherein the worksurface extends continuously between the first workstation and the second workstation.
